(19) United States
(12) Patent Application Publication
(10) Pub. No.: US 2024/0290390 A1
(43) Pub. Date: Aug. 29, 2024

(54) PROGRAMMING ERASE STATE AS LAST PROGRAM STATE DURING A PROGRAMMING CYCLE OF A NON-VOLATILE MEMORY STRUCTURE

(71) Applicant: Western Digital Technologies, Inc., San Jose, CA (US)

(72) Inventors: Yanjie Wang, San Jose, CA (US); Xiaoyu Che, San Jose, CA (US); Yi Song, San Jose, CA (US); Guirong Liang, Cupertino, CA (US)

(73) Assignee: Western Digital Technologies, Inc., San Jose, CA (US)

(21) Appl. No.: 18/225,315

(22) Filed: Jul. 24, 2023

Related U.S. Application Data
(60) Provisional application No. 63/448,527, filed on Feb. 27, 2023.

(51) Int. Cl. G11C 16/10; G06F 3/06; G11C 11/56; G11C 16/04

(52) U.S. Cl. CPC G11C 16/107; G06F 3/0611; G06F 3/0658; G06F 3/0679; G11C 11/5628; G11C 11/5671; G11C 16/0483

(57) ABSTRACT

A method for performing a programming operation with respect to a memory structure. The method comprises: (1) initiating a programming operation with respect to multiple program states of a non-volatile memory structure; (2) programming each of the multiple program states according to a programming order; and (3) after completing the programming of each of the multiple program states, programming an erase state as the final program state of the programming order.

### CROSS-REFERENCE TO RELATED APPLICATIONS

This application claims the benefit of U.S. Provisional Application No. 63/448,527, filed on Feb. 27, 2023. The entire disclosure of the application referenced above is incorporated herein by reference.

### TECHNICAL FIELD

This disclosure relates to non-volatile memory storage systems in solid-state drives or other devices, including but not limited to flash drives or embedded/removable flash packages. More specifically, this disclosure relates to systems and methods for programming memory operations in non-volatile memory structures.

### BACKGROUND

Due to emerging technology and market forces, solid-state drives (SSDs) are steadily replacing previously conventional data storage systems that rely on the rotation of magnetic mediums for reading and writing data (e.g., hard disk drives). Rather than comprising any mechanical or moving parts, solid-state memory comprises integrated circuit assemblies or interconnected flash components to provide non-volatile storage in which stored data can be persistently retained even during a planned or unplanned interruption of power. As a result, a solid-state drive is inherently faster and more robust (i.e., less susceptible to data loss and corruption), as well as consumes less power and is more compact in comparison to disk-based storage. Accordingly, non-volatile memory is a powerful storage solution with respect to many types of computing, consumer electronic, and stand-alone external storage (e.g., USB drives) devices. Advances in non-volatile memory structures have led to significant increases in their storage density capability and a reduction in their power consumption, thereby lowering the per-bit and bit-per-chip cost.

Generally, a non-volatile memory device may be comprised of one or more arrays of individual memory cells. With respect to some flash memory types, each memory cell is comprised of a floating gate that is positioned above and isolated from a channel region of a semiconductor substrate, wherein the floating gate is positioned between the source and drain regions. Also, a control gate is provided over and isolated from the floating gate, wherein a threshold voltage (Vₜₕ) of the memory cell transistor is controlled by and dependent upon an amount of charge that is retained on the transistor's floating gate. Specifically, in a switch-like manner, a minimum amount of voltage that must be applied to the control gate of the transistor before the transistor is activated to permit conduction between its source and drain regions is, therefore, determined by the level of charge that is retained on the floating gate. As a result, bit-value data can be programmed onto and erased from the cell by precisely changing the level of charge on the floating gate in order to change the threshold voltage (Vₜₕ) characteristic of the transistor. In an array structure, the memory cells are addressable by word lines (rows) and bit lines (columns).

One type of non-volatile memory storage that is defined by this general structure is referred to as NAND flash memory due to its electrical characteristics, which are based on the NAND logic gate.

As explained in detail below, the number of bits that can be stored in an individual memory cell is dependent upon the number of distinct voltage ranges that may be partitioned within the threshold voltage (Vₜₕ) window of that memory cell. For example, to store one bit of data (referred to as a binary data), the possible threshold voltage (Vₜₕ) of a memory cell can be divided into two voltage ranges, wherein the ranges are assigned as logical data “1” and “0” respectively. Accordingly, a memory cell of this storage density order may be referred to as a “single-level cell” or SLC.

By further partitioning the threshold voltage (Vₜₕ) window of a memory cell into additional distinct voltage ranges, multiple levels of information may be stored. A memory cell of this storage density order may be referred to as a “multi-state cell” or MLC. For example, in order to store two bits of data, the threshold voltage (Vₜₕ) window of a cell can be further partitioned into four distinct voltage ranges, with each range assigned a bit value equal to, for example, “11,” “10,” “01,” and “00.” Accordingly, following an erase operation, the cell's threshold voltage (Vₜₕ) is negative, which could be defined as logic “11.” As such, the positive threshold voltages (Vₜₕ) can be used for the programmed states of “10,” “01,” and “00.” In a further example, to store three bits of data, the threshold voltage (Vₜₕ) window of a cell may be partitioned into eight distinct voltage ranges, with each range assigned a bit value equal to, for example, “111,” “110,” “100,” “010,” “011,” “000,” “001,” and “101.” A memory cell of this storage density order may be referred to as a “tri-level,” “triple-level cell,” or TLC. In a further example, to store four bits of data, the threshold voltage (Vₜₕ) window of a memory cell may be partitioned into 16 distinct voltage ranges (or states), wherein each voltage range is assigned a certain bit value that is equal to, for example, “1111,” “1110,” “1100,” “1000,” “0111,” “0011,” “0001,” “0000,” “0001,” “1001,” “1101,” “1011,” “0110,” “0100,” “0101,” and “1010.” Thus, a memory cell of this storage density may be referred to, for example, as a “quad-level cell,” or QLC.

The specific relationship between the data programmed into a memory cell and the threshold voltage (Vₜₕ) levels of the memory cell depends on the data encoding pattern or data scheme adopted for the memory cells.

In addition to the increasing storage densities with respect to a single memory cell, advances in non-volatile memory array structures have led to memory cells being stacked in a vertical direction with respect to the semiconductor substrate, thus creating a three-dimensional array structure as opposed to a planar two-dimensional array structure. As described in greater detail below, the lack of separation between the charge trapping regions of the memory cells in these three-dimensional array structures provide further challenges with respect to the reliability and retention of the programmed data.

Accordingly, as the industry continues to achieve smaller sized memory cells with increased storage densities in order to store more data, this scaling of size entails certain performance and durability risks. In order to achieve the advantage of higher memory capacity for a fixed die size, smaller memory cells must be packed more closely together. Doing so, however, may result in an increased number of manufacturing, memory operation, and performance errors. For example, due to the electrical/physical behavior and, under certain circumstances, the mobile nature of electrons that are retained at the floating gate or charge trapping layer of programmed memory cells, electron interference as a result of, for example, electrical fringing effects or electrostatic coupling, can occur between neighboring memory elements following a programming operation (referred to as a “program disturb” condition), thereby problematically skewing the threshold voltage (Vₜₕ) distribution of a memory cell. Furthermore, as time elapses, a programmed memory cell may experience a lateral shift in the threshold voltage (Vₜₕ) distribution(s) of its programmed charge states as the retained electrons diffuse over time from the memory cell, which degrades the data retention of the programmed data. Generally speaking, both electron (or word line) interference and the lateral shifting phenomenon are significantly more pronounced with respect to the scalable-type memory structures, which is likely due to the compact and stacked nature of its cells and associated circuitry.

Further, as described in greater detail below, a characteristic of the transistor-type electrical behavior of non-volatile memory cells is that in order for a memory cell to be programmed, a memory cell must first be in an “erased” state. Therefore, it is not possible to reprogram an already-programmed memory cell in order to store an entirely new set of data without first performing an erase operation to place the memory cell into an “erased” state. Further, according to existing memory architectures, an erase memory operation is uniformly applied to an entire memory block. Thus, in a case in which one or more memory cells of a memory block has experienced an unintended shift in its programmed threshold voltage (Vₜₕ) distribution (due to, for example, electron diffusion occurring over time), additional erase operation cycles than otherwise intended may be required in order to completely erase these disturbed memory cells. However, because an erase operation is applied uniformly across all memory cells of a memory block, additional erase operation cycles may create a “deep erase” condition in memory cells not exhibiting a shift in their intended threshold voltage (Vₜₕ) distributions. In such a “deep erase” condition, a number of positive charges are induced at a charge trapping region of the memory cell. As a result, the “erased state” of the memory cell becomes problematically skewed. This skewed “erased state” may negatively impact the efficiency, reliability, and power consumption of any future programming/erase cycles that are applied to the now compromised memory cell.

To compensate for these types of disturbances or inaccuracies, various algorithmic methods exist for identifying, filtering and/or correcting noise and bit errors during the read operation and subsequent processing. However, these existing measure add complexity and latencies to the memory operations. In addition, these methods lose their overall efficacy as the subject memory device becomes heavily cycled. Accordingly, there is a particular need for mitigation mechanisms that can address these performance challenges at the initial point of a programming operation.

### SUMMARY

As described in detail below, various embodiments include a method for performing a programming memory operation with respect to a memory structure. The method comprises: (1) initiating a programming operation with respect to multiple program states of a non-volatile memory structure; (2) programming each of the multiple program states according to a programming order; and (3) after completing the programming of each of the multiple program states, programming an erase state as the final program state of the programming order. Furthermore, according to certain embodiments, the memory structure is a three-dimensional memory structure comprising a plurality of NAND-type memory cells. Additionally, according to certain embodiments, the programming order comprises an ascending programming order in which each program state that is being programmed is a higher programming state than the program state just previously programming. In addition, according to certain embodiments, the erase state is programmed after the completion of the programming of a highest program state of the multiple program states. Further, according to certain embodiments, the erase state is a lower program state than any program state of the multiple program states. In addition, according to certain embodiments, programming the erase state further comprises ramping down a programming voltage bias level applied to the memory structure following the completion of the programming of the highest program state of the multiple program states.

Other embodiments include a memory controller comprising: (1) a communication pathway configured to couple to a non-volatile memory structure; and (2) the memory controller is configured to: (a) initiate a programming operation with respect to multiple program states of the memory structure; (b) program each of the multiple program states in accordance with a programming order; and (c) after completing the programming of each of the multiple program states, program an erase state as the final program state of the programming order. Further, according to certain embodiments, the memory structure is comprised of a three-dimensional memory structure that comprises a plurality of NAND-type memory cells. Also, according to certain embodiments, the programming order is an ascending programming order in which each program state that is being programmed is a higher program state than the program state just previously programmed. Furthermore, according to certain embodiments, the erase state is programmed after the completion of the programming of a highest program state of the multiple program states. In addition, in accordance with certain embodiments, the erase state is a lower program state than any program state of the multiple program states. Additionally, according to certain embodiments, programming of the erase state further comprises the memory controller configured to ramp down a programming voltage bias level applied to the memory structure following completion of the programming of the highest program state of the multiple program states.

Additional embodiments include a non-volatile memory system comprised of: (1) a memory structure; and (2) a memory controller coupled to the memory structure and: (a) initiating a programming operation with respect to multiple program states of a non-volatile memory structure; (b) programming the multiple program states according a programming order; and (c) after completing the programming of each of the multiple program states, programming an erase state as the final program state of the programming order. Further, according to certain embodiments, the memory structure is a three-dimensional memory structure comprising a plurality of NAND-type memory cells. Additionally, according to certain embodiments, the programming order comprises an ascending programming order in which each program state that is being programming is a higher program state than the program state just previously programmed. Further, according to certain embodiments, the erase state is programmed after the completion of the programming of a highest program state of the multiple program states. Furthermore, according to certain embodiments, the erase state is a lower program state than any other program state of the multiple program states. Also, according to certain embodiments, programming the erase state further comprises ramping down a programming voltage bias level applied to the memory structure following the completion of the programming of the highest program state of the multiple program states.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope, the disclosure is described and explained with added specificity and detail through the use of the accompanying drawings in which:

FIG. 1 is a block diagram of a memory system, in accordance with exemplary embodiments;

FIG. 2 schematically depicts a non-volatile memory cell, in accordance with exemplary embodiments;

FIG. 3 depicts the relationship between a source-drain current I_{D} and a control gate voltage V_{CG} for four different charges Q1-Q4 that a floating gate of a non-volatile memory cell may be selectively storing at any one time and at a fixed drain voltage, in accordance with exemplary embodiments;

FIG. 4A schematically depicts a series of NAND-type memory cells organized into a string, in accordance with exemplary embodiments;

FIG. 4B schematically depicts a two-dimensional array of memory cells, comprising a plurality of NAND-type strings, such as the type depicted in FIG. 3A, in accordance with exemplary embodiments;

FIG. 5 depicts a page of memory cells being sensed or programmed in parallel, and in relation to a memory array organized in a NAND-type configuration, in accordance with exemplary embodiments;

FIGS. 6A-6C depict stages of programming four states of a population of MLC NAND-type memory cells, in accordance with exemplary embodiments;

FIGS. 7A-7C depict stages of programming eight states of a population of TLC NAND-type memory cells, in accordance with exemplary embodiments;

FIGS. 8A-8C depict stages of programming 16 states of a population of QLC NAND-type memory cells, in accordance with exemplary embodiments;

FIG. 9 depicts a vertical NAND-type string, in accordance with an exemplary embodiment;

FIG. 10 is a perspective view of a representative subsection of a monolithic three-dimensional NAND-type memory array, in accordance with exemplary embodiments;

FIG. 11 is a top view of two representative blocks of the memory array of FIG. 6, in accordance with exemplary embodiments;

FIG. 12 is a side view of a representative block of the memory array of FIG. 6, in accordance with exemplary embodiments;

FIG. 13A illustrates a memory erase operation applied to a programmable threshold transistor of a two-dimensional memory structure, in accordance with exemplary embodiments;

FIG. 13B illustrates a memory erase operation applied to a programmable threshold transistor of a three-dimensional memory structure, in accordance with exemplary embodiments;

FIG. 14 is a distribution plot that depicts an unintended lateral shift over time in the threshold voltage (Vₜₕ) distribution with respect to each program state of a population of programmed memory elements, in accordance with exemplary embodiments;

FIG. 15A schematically depicts a section of a programmed three-dimensional NAND-type memory block, in accordance with exemplary embodiments;

FIG. 15B schematically depicts the section that is shown in FIG. 15A after a period of time has passed, and during which some of the programmed electron charges have shifted or migrated from their initial position, in accordance with exemplary embodiments;

FIG. 15C schematically depicts the section that is shown in FIG. 15B subsequent to an erase operation, in accordance with exemplary embodiments;

FIG. 16 is a distribution plot that depicts a programming operation of a population of memory elements, in accordance with exemplary embodiments;

FIG. 17 is a distribution plot that depicts the effect of a “deep erase” condition on a programming operation of the population of memory elements that is at focus in FIG. 16, in accordance with exemplary embodiments;

FIG. 18 is a distribution plot that depicts a tightening of the threshold voltage (Vₜₕ) distribution with respect to each of the program states of a population of programmed memory elements as a result of initially programming an erase state during the programming cycle, in accordance with exemplary embodiments;

FIG. 19 graphically depicts an ascending sequence of the programming voltage bias levels (VPGM) applied during a programming operation in accordance with the exemplary embodiment depicted in FIG. 18;

FIG. 20 is a flow diagram generally depicting the steps of a programming operation according to the exemplary embodiment depicted in FIGS. 18 and 19;

FIG. 21 is a distribution plot that depicts a tightening of the threshold voltage (Vₜₕ) distribution with respect to each of the program states of a population of programmed memory elements as a result of programming an erase state as a last program state of the programming cycle, in accordance with exemplary embodiments;

FIG. 22 graphically depicts a sequence of programming voltage bias levels (VPGM) applied during a programming operation that is in accordance with the exemplary embodiment depicted in FIG. 21; and

FIG. 23 is a flow diagram generally depicting the steps of a programming operation according to the exemplary embodiment depicted in FIGS. 21 and 22.

### DETAILED DESCRIPTION

The following description is directed to various exemplary embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the detailed explanation of any specific embodiment is meant only to be exemplary of that embodiment and is not intended to suggest that the scope of the disclosure, including the claims, is limited to that particular embodiment.

The several aspects of the present disclosure may be embodied in the form of an apparatus, system, method, or computer program process. Therefore, aspects of the present disclosure may be entirely in the form of a hardware embodiment or a software embodiment (including but not limited to firmware, resident software, micro-code, or the like), or may be a combination of both hardware and software components that may generally be referred to collectively as a “circuit,” “module,” “apparatus,” or “system.” Further, various aspects of the present disclosure may be in the form of a computer program process that is embodied, for example, in one or more non-transitory computer-readable storage media storing computer-readable and/or executable program code.

Additionally, various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that comprises customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it comprises one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Further, the terms “program,” “software,” “software application,” and the like as may be used herein, refer to a sequence of instructions that is designed for execution on a computer-implemented system. Accordingly, a “program,” “software,” “application,” “computer program,” or “software application” may include a subroutine, a function, a procedure, an object method, an object implementation, an executable application, an applet, a servlet, a source code, an object code, a shared library/dynamic load library and/or other sequence of specific instructions that is designed for execution on a computer system.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that comprises the element.

The terms “a,” “an,” and “the” also refer to “one or more” unless expressly specified otherwise. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or mores,” “ones or more,” and/or “ones or mores” according to set theory, unless expressly specified otherwise.

In the detailed description that follows, reference is made to the appended drawings, which form a part thereof. It is recognized that the foregoing summary is illustrative only and is not intended to be limiting in any manner. In addition to the illustrative aspects, example embodiments, and features described above, additional aspects, exemplary embodiments, and features will become apparent by reference to the drawings and the detailed description below. The description of elements in each figure may refer to elements of proceeding figures. Like reference numerals may refer to like elements in the figures, including alternate exemplary embodiments of like elements.

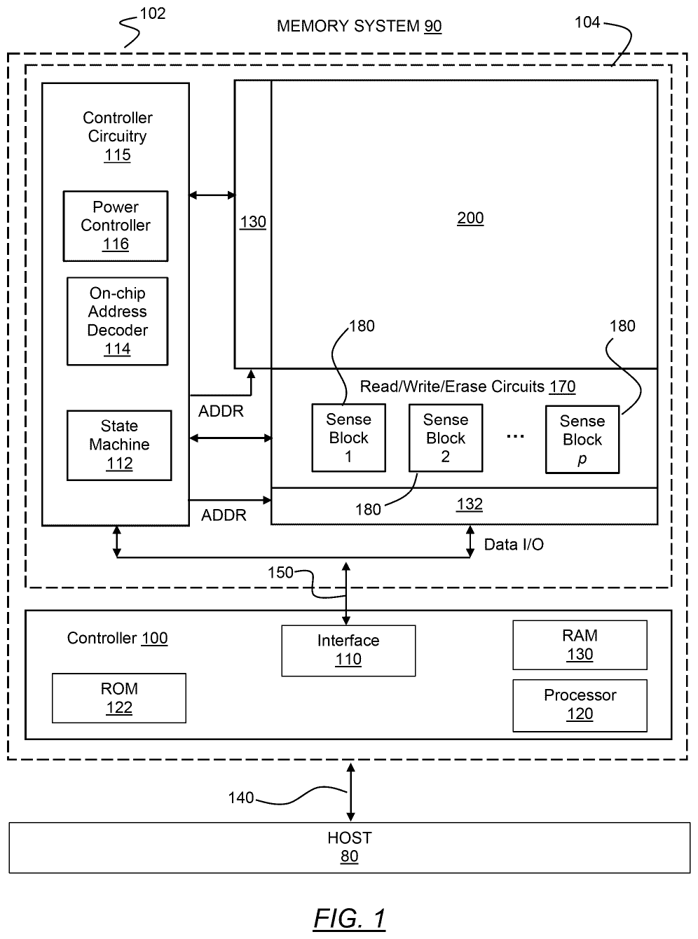

Referring now to the drawings in detail and beginning with FIG. 1, there is depicted an exemplary embodiment of a memory system 90 and is an illustration of its main hardware components. In this particular embodiment, the memory system 90 operates and is in communication with a host device 80 through a host interface. Further, the memory system 90 comprises a memory device 102 whose operations are controlled by a controller 100. The host device 80 may comprise any device or system that utilizes the memory system 90 (e.g., a computing device). Accordingly, the memory system 90 may be in the form of a removable memory card or an embedded memory system. For example, the memory system 90 may be embedded in a solid-state drive that is installed in a laptop computer. In another example, the memory system 90 may be embedded within the host device 80 such that the host 80 and the memory system 90 (including controller 100) are formed on a single integrated circuit chip. In embodiments in which the memory system 90 is implemented within a memory card, the host device 80 may include a built-in receptacle for the one or more types of memory cards or flash drives (e.g., a universal serial bus (USB) port, or a memory card slot). Further, the host 80 may use adapters in which a memory card is plugged.

Still referring to FIG. 1, as described in detail below, the memory device 102 may comprise one or more memory arrays 200 of a plurality of non-volatile memory cells that are distributed over one or more integrated circuit chips. And, in accordance with this particular embodiment, the controller 100 may include several components that may include, but are not limited to, interface circuits 110, a processor 120, ROM (read-only memory) 122, RAM (random access memory) 130, and additional components. The controller 100 may, for example, be in the form of one or more application-specific integrated circuits (ASIC) in which the components included in such an ASIC depend on the particular application.

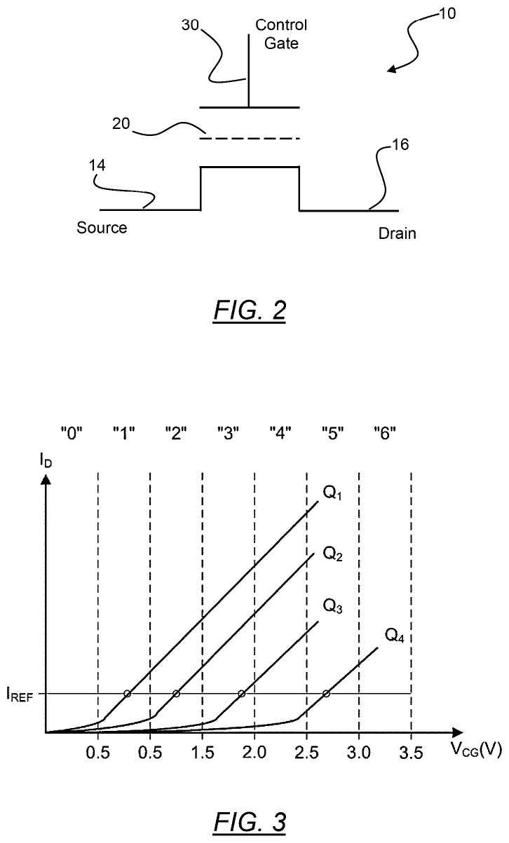

With respect to the memory array 200 itself, FIG. 2 is a schematic depiction of an individual non-volatile memory cell 10 in accordance with an exemplary embodiment. As is mentioned above, the memory cell 10 may be implemented by a field-effect transistor having a charge storage unit 20, such as a floating gate or a dielectric layer. In addition, the memory cell 10 comprises a source region 14 and a drain region 16. Further, a control gate 30 is positioned above the floating gate 20. Example types of non-volatile memory cells having this general structure include, but are not limited to, electrically erasable programmable read-only memory (EEPROM) and flash EEPROM, NAND (NOT-AND)-type cells, and memory devices utilizing dielectric storage elements (e.g., NROM™). In operation, the memory state of a cell (e.g., programmed or erased) may, in accordance with certain embodiments, be read by sensing the conduction current across the source and drain electrodes of the memory cell when a reference voltage is applied to the control gate 30. More specifically, for each given charge on the floating gate 20 of a memory cell, a corresponding conduction current with respect to a fixed reference control gate voltage may be detected. Accordingly, as is described above, the range of charges programmable onto the floating gate defines a corresponding threshold voltage window or a corresponding conduction current window of the memory cell 10. Alternatively, rather than detecting the conduction current among a partitioned current window, it is possible to set the threshold voltage for a given memory state under test at the control gate 30 and detect if the resulting conduction current is higher than or lower than a threshold current (i.e., a cell-read reference current). In one such exemplary implementation, detection of the conduction current relative to a threshold current is accomplished by examining a discharge rate of the conduction current through the capacitance of a respective bit line (BL).

FIG. 3 provides a graphical illustration of the correlation between the source-drain current I_{D} and control gate voltage V_{CG} for, for example, a non-volatile memory cell 10 having four different charge states Q1-Q4 that the floating gate may be selectively storing at any given time. As shown, with a fixed drain voltage bias, there exists four solid I_{D} versus V_{CG} curves representing four charge levels that can be programmed on a floating gate of the memory cell, wherein the four charge levels respectively correspond to four of eight possible memory states. Therefore, as an example, the threshold voltage window of a population of memory cells may range from 0.5 V to 3.5 V. In such an example, seven programmed memory states assigned as “0,” “1,” “2,” “3,” “4,” “5,” “6,” respectively, and one erased state (which is not shown in FIG. 3), may be demarcated by partitioning the threshold window into regions at intervals of 0.5 V each. Accordingly, if a reference current, I_{REF}, of 2 μA is used as shown, then a cell programmed with Q1 voltage may be considered to be in a memory state “1” as its curve intersects with I_{REF} in the region of the threshold window that is demarcated by the voltage range V_{CG}=0.5 V and 1.0 V. Similarly, Q4 is in a memory state “5.”

Thus, as mentioned above, the more states that a memory cell 10 is made to store, the more finely divided is its threshold voltage window. For example, in a memory cell that has a threshold voltage window ranging from −1.5 V to 5 V, thereby providing a possible maximum width of 6.5 V, and is to store 16 memory states, each state may only occupy a voltage range of from 200 mV to 300 mV. Such a narrow voltage range will require higher precision in programming and reading operations in order to achieve the required resolution.

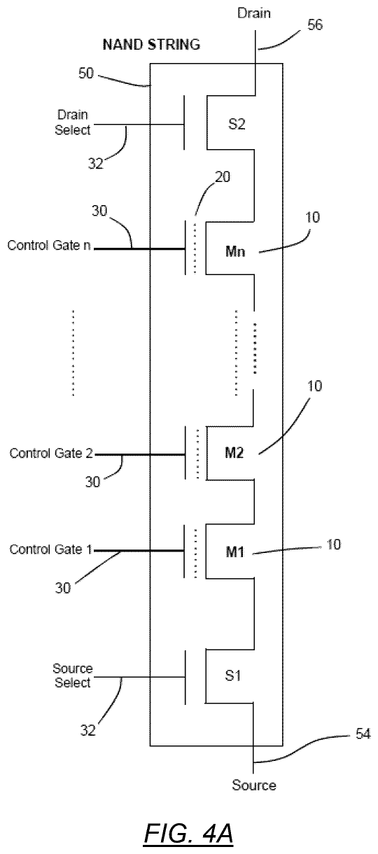

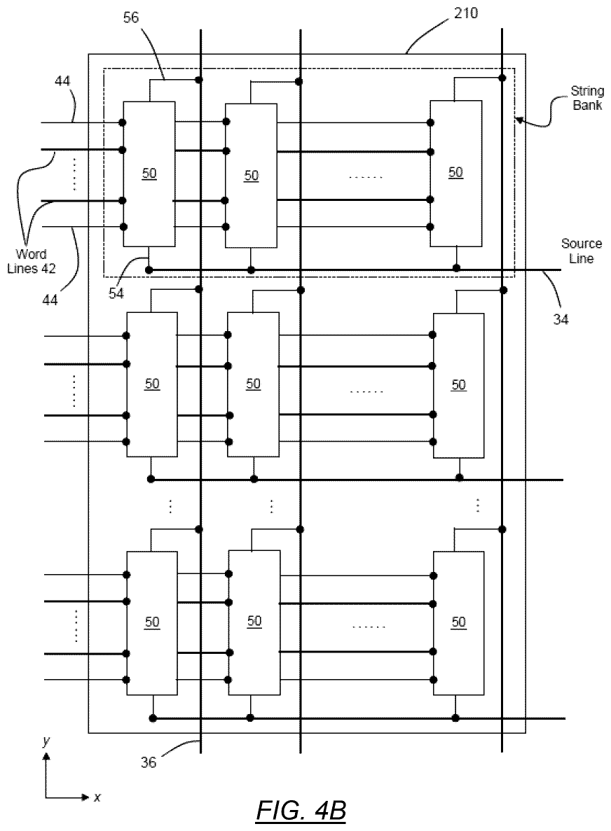

According to certain exemplary embodiments, the individual memory cells 10 are organized into strings in which the memory cells are placed in series. For example, depicted in FIG. 4A is an exemplary embodiment of a string 50 comprising NAND-type memory cells in which the series of the cells' respective transistor elements M1, M2, . . . , Mn (wherein “n” may equal 4, 8, 16, or higher) are daisy-chained with respect to their sources and drains. Further, as mentioned above with respect to FIG. 2, each memory cell's transistor 10 in the string 50 has a charge storage element 20 (e.g., a floating gate) for storing a certain amount of charge so as to represent an intended memory state of that cell, wherein each memory transistor 10 comprises a control gate 30 that allows control over the read and write memory operations. Present at the source terminal 54 and the drain terminal 56 of the string 50 are select transistors S1, S2 that control the transistor's connection to the outlying memory array. Specifically, when the source select transistor S1 is turned on, the source terminal 54 of the string 50 is coupled to a source line (SL). Likewise, when the drain select transistor S2 is turned on, the drain terminal 56 is coupled to a bit line (BL) of the memory array.

Expanding outward a hierarchical level, FIG. 4B is a schematic diagram depicting an exemplary embodiment of a memory array 200 (such as memory array 210) comprised of a plurality of NAND strings 50 of the type illustrated in FIG. 3A. Along each column of NAND strings 50, a bit line (BL) 36 is coupled to the drain terminal 56 of each NAND string 50. In addition, along each bank of NAND strings 50, a source line (SL) 34 is coupled to the source terminals 54 of each NAND string 50. Further, the control gates 30 of the memory transistors 10 in a row of memory cells in the bank of NAND strings 50 are connected to the same word line (WL) 42. Therefore, when an addressed memory transistor 10 within a NAND string 50 is read or verified during a programming operation, an appropriate voltage is applied to its control gate 30. Concurrently, the remaining non-addressed memory transistors 10 within the NAND string 50 are fully turned on by applying a sufficient voltage to their respective control gates 30. As a result, an electrically conductive pathway is created from the source of the addressed memory transistor 10 to the source terminal 54 of NAND string 50, and from the drain of the addressed memory transistor 10 to the drain terminal 56 of the cell.

Further, the control gates 32 of the select transistors S1, S2 of each NAND string 50 in the memory array 210 provide control access to the NAND string at its source terminal 54 and drain terminal 56. The control gates 32 of the select transistors S1, S2 along a row in a bank of NAND strings 50 are connected to the same select line 44. Thus, an entire row of memory cells 10 in a bank of NAND strings 50 can be addressed by applying the appropriate voltages on the word lines (WL) 42 and select lines 44 of the bank of NAND strings 50.

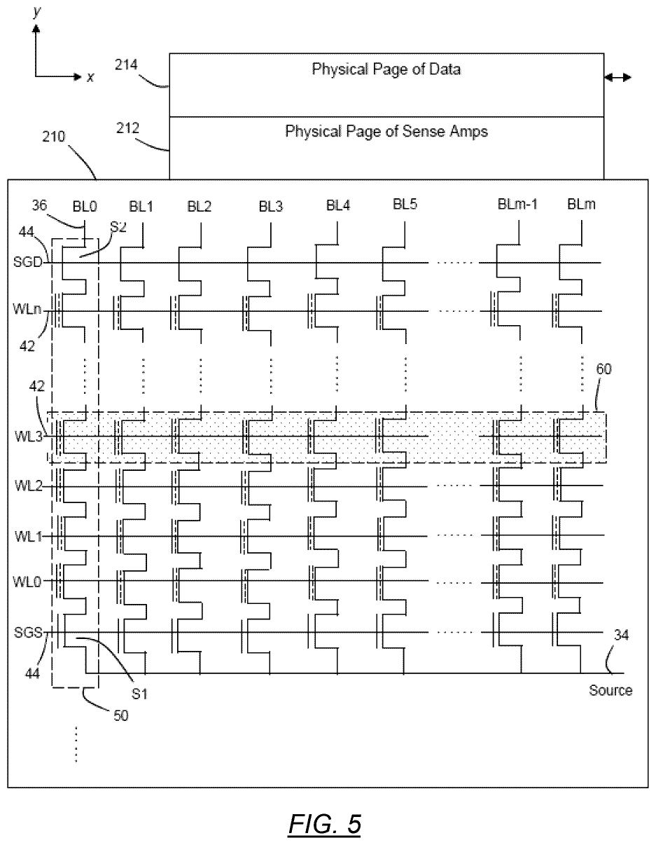

Referring now to FIG. 5, there is depicted a detailed illustration of one bank of NAND strings 50 of a memory array 210 according to an exemplary embodiment thereof. This view is particularly useful in visualizing a row-by-row configuration of the memory array 210, wherein each row may be referred to as a “page.” Accordingly, a physical page (e.g., page 60 denoted in FIG. 5) is a group of memory cells 10 that is enabled to be sensed or programmed in parallel. In fact, in such a configuration, a page is the smallest unit of the memory device that may be programmed or written to. Programming of a page is accomplished by a corresponding page of sense amplifiers (SA) 212, wherein each sense amplifier may be coupled to a respective NAND string 50 via a bit line (BL) (see e.g., the bit lines BL0, BL1, BL2, . . . , BLm-1, and BLm, as depicted in FIG. 5). Thus, a page 60 is enabled by the control gates of the plurality of memory cells 10 in page 60, which are connected to a common word line (WL) 42, and each memory cell 10 of the page 60 is accessible by a sense amplifier via a bit line 36. Accordingly, when programming or sensing a page 60 of memory cells 10, a programming or sensing voltage is respectively applied to the common word line (e.g., word line WL3 with respect to page 60) together with the appropriate voltages on the bit lines.

Regarding the manner in which data is programmed and erased, it is important to note that, with respect to flash memory, a memory cell must be programmed from an erased state. In other words, a floating gate 20 must first be emptied of charge, thereby placing the memory cell in an erased state, before a programming operation can subsequently add a desired amount of charge back to the floating gate 20. Thus, the level of charge on a floating gate 20 cannot be incrementally increased or decreased from its previous programmed level. Therefore, it is not possible for update data to overwrite the existing data of a memory cell 10. Rather, the update data must be programmed to a previous unwritten location.

For purposes of promoting performance in erase operations, an array 210 of memory cells 10 is, for example, divided into a large number of blocks of memory cells, wherein a block is the smallest unit of the memory device in which the memory cells contained may be erased together. Furthermore, each block of memory cells 10 may be divided into a number of physical pages 60 wherein, as mentioned above, a programming operation is conducted page by page. Accordingly, a logical page is a unit of programming or reading that contains a number of bits equal to the number of memory cells 10 in a given physical page. For example, in a memory device of the SLC-type in which one bit of data is stored in each memory cell 10, one physical page 60 stores one logical page of data. Accordingly, in a memory device of the MLC-type in which two bits of data are stored in each memory cell 10, one physical page 60 can store two logical pages of data. As such, one or more logical pages of data are typically stored in one row (i.e., page 60) of memory cells. A page 60 can store one or more sectors wherein a sector is comprised of both user data and overhead data. In an exemplary embodiment, individual pages 60 may be divided into segments in which each segment contains the fewest number of memory cells 10 that may be written at one time in a basic programming operation.

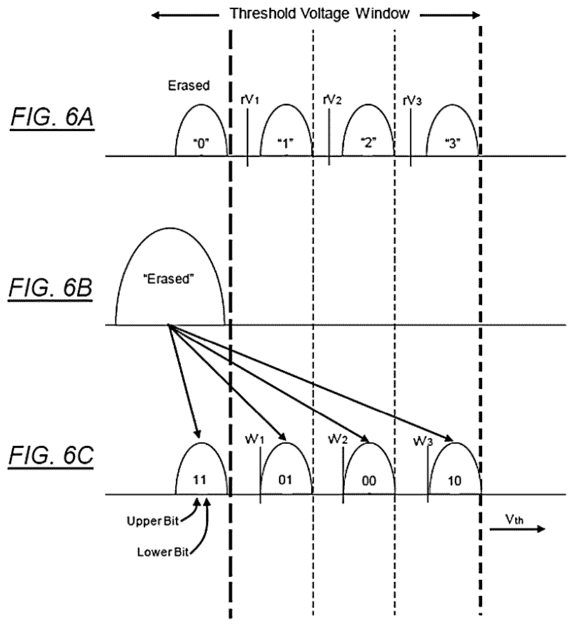

To illustrate an exemplary embodiment of the programming stages of a MLC-type memory device comprising a population of four-state memory cells, reference is made to FIGS. 6A-6C. In FIG. 6A, there is depicted a population of memory cells in which the characteristic threshold voltage window is divided into four distinct voltage distributions wherein each distribution corresponds to a programmable memory state (i.e., memory states “0,” “1,” “2,” and “3”). FIG. 6B illustrates an initial distribution of “erased” threshold voltages for an erased memory. In FIG. 6C, much of the memory cell population is programmed such that the initial “erased” threshold voltage of a given memory cell 10 is moved to a higher value into one of the three divided voltage zones demarcated by verify levels vV₁, vV₂, and vV₃. Accordingly, each memory cell can be programmed to one of the three programmable states “1,” “2,” and “3,” or remain in the “erased” state. On a bit level, a 2-bit code having a lower bit and an upper bit can be used to represent each of the four memory states. For example, as depicted in FIG. 6C, the memory states “0,” “1,” “2,” and “3” may be assigned bit values “11,” “01,” “00,” and “10” respectively. In such an example, the 2-bit data may be read from the memory by sensing in a “full-sequence” mode where the two bits are sensed together by sensing relative to the corresponding read demarcation threshold voltages rV₁, rV₂, and rV₃ in three sub-passes respectively.

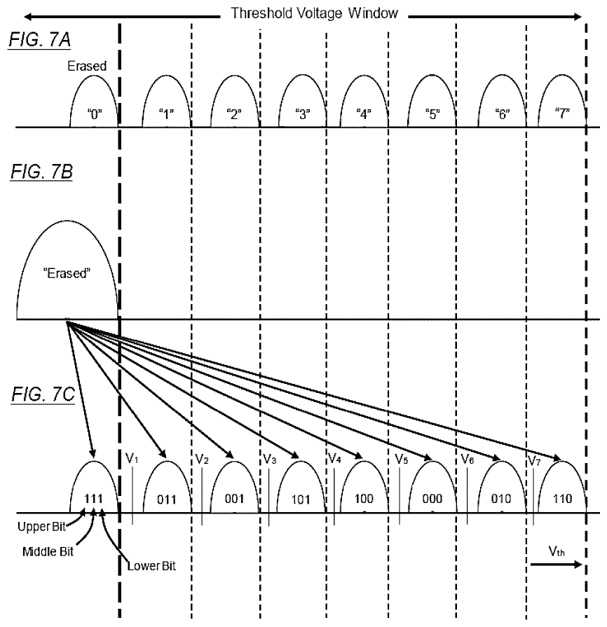

Similarly, FIGS. 7A-7C illustrate programming stages of a TLC-type memory device comprising a population of eight-state memory cells, each cell being programmable into eight distinct distributions of threshold voltages that, in accordance with this particular embodiment, represent memory states “0,” “1,” “2,” “3,” “4,” “5,” “6,” and “7,” respectively (as shown in FIG. 7A). Thus, FIG. 7B depicts an initial distribution of “erased” threshold voltages for an erased memory. Further, FIG. 7C depicts an example of the memory after many of the memory cells have been programmed. As a result, a cell's threshold voltage is moved higher into one of the distinct voltage ranges demarcated by levels V₁, V₂, V₃, V₄, V₅, V₆, and V₇. Accordingly, each memory cell can be programmed to one of the seven programmed states “1” through “7,” or can remain unprogrammed in the “erased” state. As a consequence of the programming, the initial distribution of the “erased” state as shown in FIG. 7B becomes narrower as indicated by the “0” state in FIG. 7C. In this case, a 3-bit code having lower, middle, and upper bits can be used to represent each of the memory states (i.e., “111,” “011,” “001,” “101,” “100,” “000,” “010,” and “110”) and the 3-bit data may also be read from the memory by sensing in the “full-sequence” mode where the three bits are sensed together by sensing relative to the demarcation threshold values V₁ through V₇ in seven sub-passes respectively.

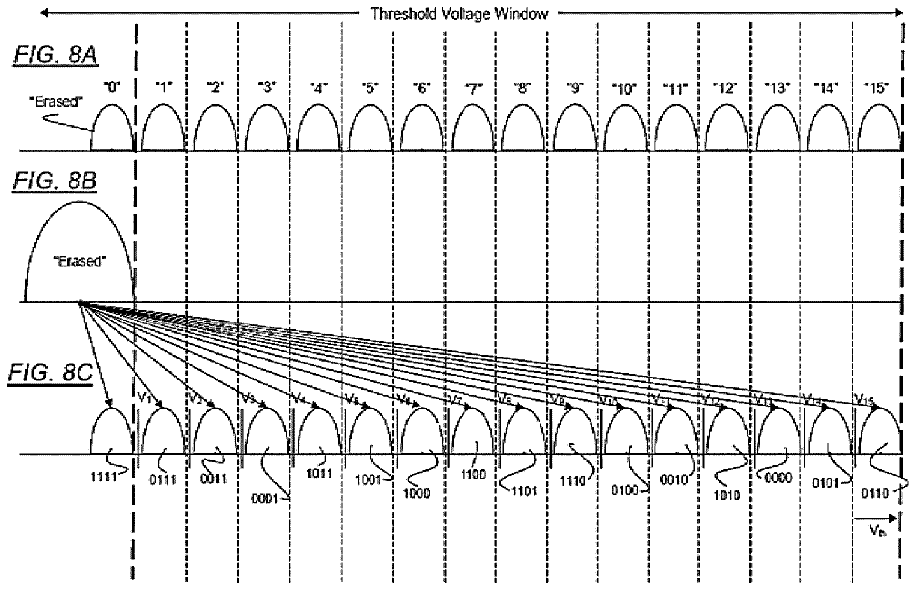

Continuing in a similar manner, FIGS. 8A-8C illustrate the programming stages of a QLC-type memory device comprising a population of 16-state memory cells, each cell being programmable into 16 distinct distributions of threshold voltages that, in accordance with this particular embodiment, represent memory states “0,” “1,” “2,” “3,” “4,” “5,” “6,” “7,” “8,” “9,” “10,” “11,” “12,” “13,” “14,” and “15,” respectively (as shown in FIG. 8A). Accordingly, FIG. 8B depicts an initial distribution of “erased” threshold voltages for an erased memory; whereas FIG. 8C depicts an example of the memory after programming. As depicted, a cell's threshold voltage is moved higher into one of the distinct voltage ranges, as demarcated by levels V₁, V₂, V₃, V₄, V₅, V₆, V₇, V₈, V₉, V₁₀, V₁₁, V₁₂, V₁₃, V₁₄, and V₁₅. Therefore, each memory cell can be programmed to one of 15 programmed states “1” through “15,” or can remain unprogrammed in the “erased” state. Again, as a consequence of the programming, the initial distribution of the “erased” state as shown in FIG. 8B becomes narrower as indicated by the “0” state in FIG. 8C. Thus, according to this particular distribution, a 4-bit code having lower, middle, upper and top bits can be used to represent each of the memory states (i.e., “1111,” “1110,” “1100,” “1101,” “0101,” “0100,” “0000,” “0010,” “0110,” “0111,” “0011,” “0001,” “1001,” “1011,” “1010,” and “1000”).

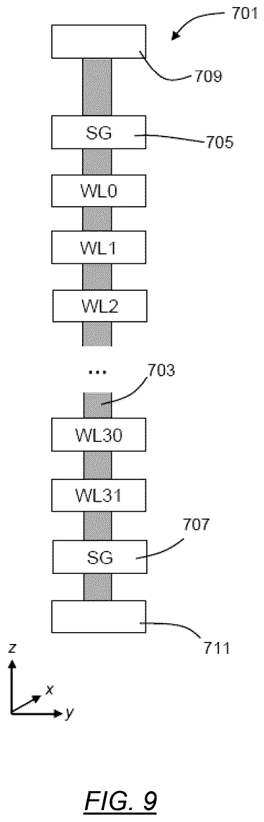

In FIGS. 4A-4B and 5 and the foregoing corresponding description, there is generally described a two-dimensional (or planar) memory array 210 (lying in a x-y plane, for example), which may comprise NAND-type memory cells. However, in an alternative configuration, a memory array may be in the form of a three-dimensional array that, unlike being formed on a planar surface of a semiconductor wafer, the array extends upwards from the wafer surface and comprises stacks or columns of memory cells extending vertically in an upwards direction (for example, in a z direction that is perpendicular to the x-y plane). As a result, three-dimensional memory structures increase the storage density but consume less chip surface. For example, in FIG. 9 there is depicted an exemplary embodiment of a 3D NAND-type string 701, which is operated in a similar manner as a two-dimensional NAND-type string, such as the NAND-type string 50 described above. In this configuration, a memory cell is formed at the juncture of a vertical bit line (BL) (see e.g., the local bit line 703) and a word line (see e.g., word lines WL0, WL1, etc.), wherein a charge trapping layer located between the local bit line 703 and an intersecting word line (WL) stores charge. In order to form such a vertical string 701, stacks of word lines are formed and memory holes are etched at the appropriate locations where the cells are to be formed, wherein each memory hole is lined with a charge trapping layer and filled with a suitable local bit line/channel material. Additionally, dielectric layers are included for the necessary isolation. Further, located at either end of the NAND-type string 701 are select gates 705, 707, which allow for the selective connection to, or isolation from, external elements 709, 711 that include, for example, conductive lines (such as common source lines or bit lines) that serve large numbers of strings 701 of a memory array. In the particular embodiment shown in FIG. 9, the vertical NAND-type string 701 has 32 memory cells (i.e., at the juncture between the local bit line 703 and word lines 0 through 31) that are connected in series. However, a NAND-type string 701 may comprise any suitable number of memory cells.

Referring back to the overall architecture of a memory system that is, for example, depicted in FIG. 1, there is shown a schematic depiction of a typical arrangement of an example memory device 102. In this particular embodiment, the memory device 102 comprises one or more memory die 104 wherein each memory die 104 may include a two- or three-dimensional memory structure 200, such as the two- and three-dimensional memory arrays described above with respect to FIGS. 4A-4B, 5 and 9, as well as the associated control circuitry 115 and read/write/erase circuits 170. For example, memory structure 200 may comprise a monolithic three-dimensional memory structure in which multiple memory levels are formed above (rather than in) a single substrate, such as a wafer, without any intervening substrates. Further, the memory structure 200 may be comprised of any type of non-volatile memory monolithically formed in one or more physical levels of arrays of memory cells having an active area that is disposed above a silicon substrate. Such a memory structure may be in a non-volatile memory device in which the circuitry that is associated with the operation of the memory cells may be above or within the substrate.

Still referring to FIG. 1, the memory structure 200 is accessible by the read/write/erase circuits 170 by way of a row decoder 130 and a column decoder 132. As previously described, individual memory cells of the memory structure 200 are addressable via a set of selected word lines (WL) and bit lines (BL). Specifically, the row decoder 130 selects the one or more word lines and the column decoder 132 selects one or more bit lines in order to apply the appropriate voltages to the respective gates of the addressed memory cells. As shown in FIG. 1, the read/write/erase circuits 170 comprise multiple sense blocks 180 (Sense Block 1, Sense Block 2, . . . . Sense Block p) that are connectable via bit lines to the memory elements of the memory structure 200. The sense blocks 180 allow memory cells connected to a common word line (referred to as a “page” of memory cells) to be read or programmed in parallel. In some embodiments, a controller 100 is included in the same memory device 102 as the one or more memory die 104 or, in other embodiments, the controller 100 may be located separate from the memory die 104. In some embodiments, the controller 100 may be on an entirely different die from the memory die 104. Further, in certain embodiments, each memory die 104 may have its own controller 100 or, in other embodiments, one controller 100 may communicate amongst multiple memory die 104. According to the exemplary embodiment of FIG. 1, commands and data are transferred between the host 80 and the controller 100 by way of a data bus 140, and between the controller 100 and the one or more memory die 104 via lines 150. According to certain embodiments, the memory die 104 include input and/or output (I/O) pins that connect to the lines 150.

According to certain exemplary embodiments, the controller 100 manages data that is stored in the memory device 102 and communicated with the host 80. The controller 100 may have various functionalities that include, for example, formatting the memory to ensure it is operating properly, map out bad memory components, and allocate spare memory cells to be substituted for future failed cells. In operation, when a host 80 needs to read data from or write data to the memory, it will communicate with the controller 100. If the host provides a logical address to which data is to be read/written, the controller 100 can convert the logical address received from the host to a physical address in the memory. Alternatively, the host can provide the physical address. In further embodiments, the controller 100 can perform various memory management functions such as, but not limited to, wear leveling (distributing writes in order to avoid repeatedly writing, and thereby wearing out, specific blocks of memory) and garbage collection in which, for example, valid pages of data are culled (or moved) from a full memory block in order for the entire block to be erased and reused.

The components of the controller 100 may take the form of a packaged functional hardware unit (e.g., an electrical circuit) designed for use with other components, a portion of a program code (e.g., software or firmware) executable by a (micro) processor or processing circuitry that usually performs a particular function of related functions, or a self-contained hardware or software component that interfaces with a larger system, for example. In some exemplary embodiments, each module may comprise an application-specific integrated circuit (ASIC), a Field Programmable Gate Array (FPGA), a circuit, a digital logic circuit, an analog circuit, a combination of discrete circuits, gates, or any other type of hardware or combination thereof. Alternatively, or in addition, each module may include software stored in a processor readable device (e.g., memory) to program a processor for controller 100 to perform the desired functions.

Additionally, the control circuitry 115 cooperates with the read/write/erase circuits 170 in performing memory operations (e.g., read, program, erase, etc.) with respect to memory structure 200, and includes, for example, a state machine 112, an on-chip address decoder 114, and a power control module 116. The state machine 112 provides die-level control of memory operations that include, for example, programming certain memory cells to different final target states. Further, the on-chip address decoder 114 provides an address interface between the addresses used by host 80 or controller 100 to the hardware address used by the row and column decoders 130, 132. The power control module 116 controls the power and voltages that are supplied to the word lines and bit lines during memory operations. As such, the power control module 116 may comprise drivers for word line layers (with respect to a 3D memory configuration), select transistors, and source lines. Also, the power control module 116 may include charge pumps for generating voltages. The sense blocks 180 include the bit line drivers. Any one or any combination of control circuitry 115, state machine 112, decoders 114/130/132, power control module 116, sense blocks 180, read/write/erase circuits 170, and/or controller 100 can be considered a control circuit that performs the functions described herein.

As described above, memory cells of the memory structure 200 may be arranged in a single memory device level in an ordered two-dimensional array of a plurality of rows and/or columns. Alternatively, a three-dimensional memory array may be arranged such that memory cells occupy multiple planes or multiple memory device levels, thereby forming a structure that has three dimensions (e.g., in the x, y, and z directions, wherein the z direction is substantially perpendicular and the x and y directions are substantially parallel to the major surface of the semiconductor substrate). In some exemplary embodiments, a three-dimensional memory structure 200 may be vertically arranged as a stack of multiple two-dimensional memory array device levels. In other exemplary embodiments, the three-dimensional memory structure 200 is arranged as multiple vertical columns (wherein each column extends substantially perpendicular to the major surface of the substrate, i.e., in the z direction) with each column having multiple memory cells. In this example, the vertical columns may be arranged in a two-dimensional configuration (i.e., in the x-y plane), thereby forming a three-dimensional arrangement in which the memory cells are on multiple vertically stacked memory planes. Other configurations of memory elements in three dimensions can also constitute a three-dimensional memory array. However, generally speaking, a three-dimensional NAND array may be constructed by tilting a two-dimensional memory structure, such as structures 50 and 210 of FIGS. 4A-4B and 5, respectively, in the vertical direction that is perpendicular to the x-y plane (i.e., the z direction), such that each y-z plane of the three-dimensional structure corresponds to the page structure of FIG. 5, wherein each plane is at differing locations along the x axis. As a result, the global bit lines (e.g., BL0, . . . , BLm, of FIG. 4) each run across the top of the memory structure to an associated sense amplifier (e.g., SA0, . . . , SAm). Accordingly, the word lines (e.g., WL0, . . . , WLn, of FIG. 4), and the source and select lines (e.g., SSL0, . . . , SSLn, and DSL0, . . . , DSLn, respectively) extend in the x direction, with the bottom of each NAND string (e.g., string 50) connected to a common source line.

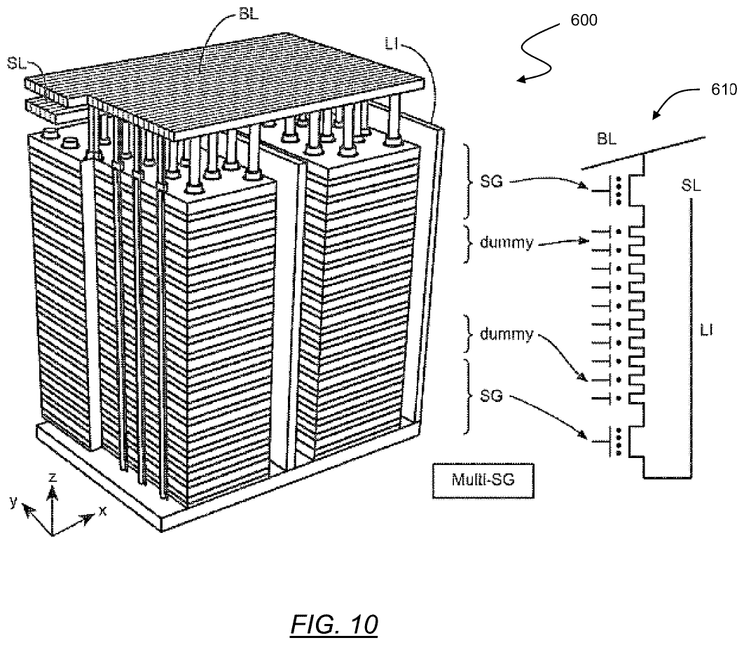

Referring now to FIG. 10, there is depicted an oblique perspective view of an example subsection of an embodiment of a three-dimensional NAND memory array 600 of the Bit Cost Scalable (“BiCS”) type in which one or more memory device levels is formed above a single substrate. The example subsection corresponds to two of the page structures shown in FIG. 4B wherein, depending upon the particular embodiment, each may correspond to a separate memory block or may be different extensions of the same block. According to this embodiment, rather than lying in the same y-z plane, the NAND strings are pressed in the y-direction such that the NAND strings have a staggered configuration in the x-direction. Further, at the top of the array 600, the NAND strings are connected along global bit lines (BL) that span multiple of these subsections of the array 600 that run in the x-direction. In addition, global common source lines (SL) also run across multiple subsections of the memory array 600 in the x-direction and are connected to the sources at the bottom of the NAND strings by a local interconnect (LI) that operates as the local common source line of the individual extension. However, dependent upon the embodiment, the global source lines (SL) can span the whole, or just a subsection, of the memory array 600. Depicted on the right side of FIG. 10 is a schematic representation of the fundamental elements of one of the vertical NAND strings 610 of the memory array 600. Similar to the NAND string 50 of FIG. 4A, the string 610 is comprised of a series of interconnected memory cells. The string 610 is connected to an associated bit line (BL) through a drain select gate (SGD). A source select gate (SDS) connects the string 610 to a global source line (SL) through an associated local source line (LI). Further included in this particular embodiment are several dummy cells located at the ends of the string 610. Due to their proximity to select gates (SGD, SDS) and, thereby, their susceptibility to disturbs, the dummy cells are not used to store user data.

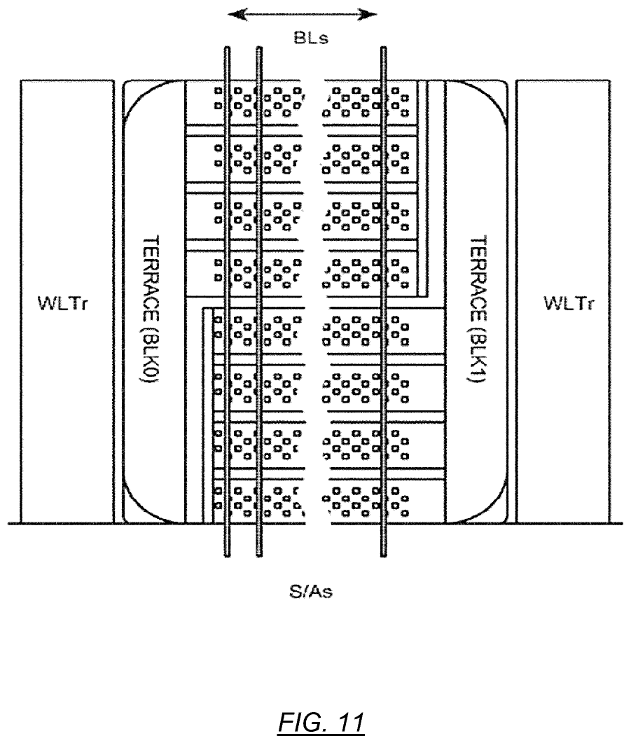

Turning to FIG. 11, there is shown a top view of two representative blocks (i.e., BLK0 and BLK1) of the array structure 600 of FIG. 10. According to this particular embodiment, each block is comprised of four extensions that extend from left to right. Further, the word lines and the select gate lines of each level also extend from left to right, wherein the word lines of the different extensions of the same block are commonly connected at a “terrace” from which they receive their various voltage levels by way of word line select gates (WLTr). It should also be noted that the word lines of a given layer of a block may be commonly connected on the far side from the terrace. Also, the selected gate lines can be individual, rather than common, for each level, thereby allowing for each extension to be individually selected. In addition, the bit lines (BLs) run vertically as depicted, and connect to the sense amplifier circuits (SAs) where, depending on the embodiment, each sense amplifier can correspond to a single bit line or be multiplexed to several bit lines.

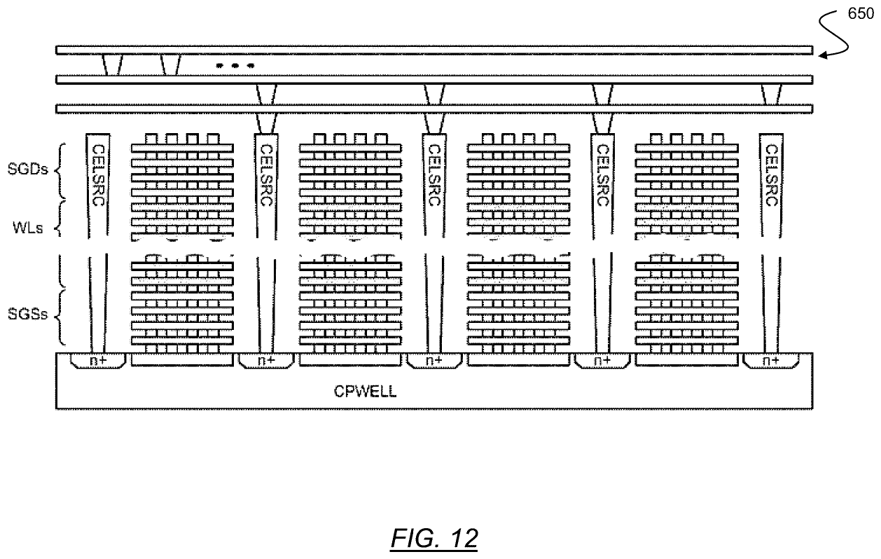

The side view that is provided in FIG. 12 shows the four extensions of an individual block 650 of the array structure 600 of FIG. 10 in greater detail. According to this particular embodiment, select gates (SGD, SDS) at either end of the NAND strings are formed with four layers, with the word lines (WLs) therebetween, all formed over a CPWELL. Accordingly, in order to select a given extension, the voltage level (VSG) of the select gates is set and the word lines (WLs) are biased according to the operation, either at a read voltage (VCGRV) for the selected word lines (WLs), or at a read-pass voltage (VREAD) for the non-selected word lines (WLs). The non-selected extensions may then be cut off by setting their select gates accordingly.

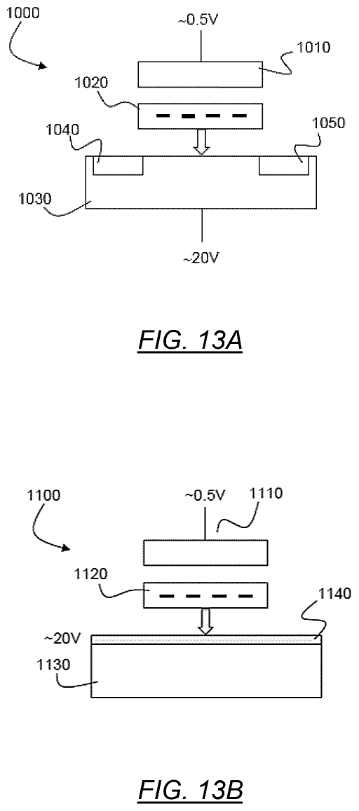

Returning now to the programming and erase memory operations with respect to non-volatile memory, these two operations may be generally described in the following manner. As described above, each cell comprises a floating gate MOS transistor or charge trapping layer, wherein the floating gate (FG) or charge trapping layer is an electrically isolated conductor. Therefore, when programming a memory cell, a relatively high voltage is applied to the control gate of the memory cell (in the case of a two-dimensional array) or the appropriate word line (in the case of a three-dimensional array) and, as a result, electrons are then injected into the floating gate by means of, for example, Fowler-Nordheim (F-N) Tunneling. Data bits are then stored by trapping charges on the floating gate, wherein the logic value is defined by its threshold voltage and the amount of electrical charge that is stored. Conversely, in order to erase a programmed memory cell, electrons in the floating gate are removed to the source and/or semiconductor substrate by way of, for example, a process referred to as quantum tunneling. More specifically, in some exemplary embodiments, electrons are removed from the floating gate or the charge trapping layer by applying a low voltage to the control gate as well as increasing the channel voltage to a high voltage, thereby creating an electric field that causes the electrons to then be pushed back into the semiconductor substrate. This process is diagrammatically shown in FIG. 13A, which generally depicts a two-dimensional NAND-type memory cell configuration 1000 comprising a control gate 1010, a floating gate 1020, and the underlying semiconductor substrate 1030 (e.g., polysilicon) comprising the memory cell's source and drain terminals (see 1040 and 1050, respectively). According to this particular embodiment, a relatively low voltage (0.5 V, for example) is applied to the control gate 1010 and a relatively high voltage VERA (20 V, for example) is applied to the substrate body 1030, causing the electron charges (-) trapped at the floating gate 1020 to be pushed back into substrate 1030. Similarly, depicted in FIG. 13B is a diagrammatic view of a general erase process with respect to a three-dimensional NAND-type memory cell configuration 1100, according to an exemplary embodiment. Here, a relatively low voltage (e.g., ˜0.5 V) is applied to the appropriate word line 1110 and a relatively high voltage VERA (e.g., ˜20 V) is applied to a channel 1140 of memory structure 1130, the channel being comprised of holes. As a result, the electron charges (-) are pushed out of the charge trapping layer 1120.

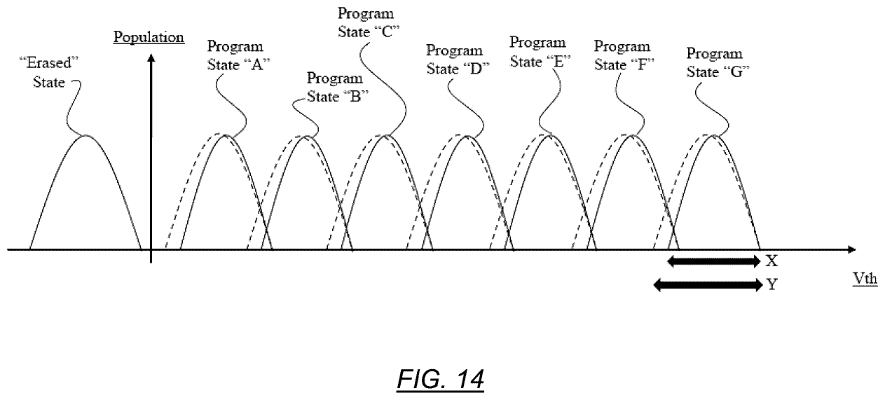

As mentioned above, it is possible that the threshold voltage (Vₜₕ) distribution margin/range of a programmed state may become skewed (or widened) as a result of electron interference occurring during the programming of higher program states and/or between neighboring memory elements (e.g., a “program disturb” condition), which influences electron charges that are retained at the floating gate or charge trapping layer of the memory structure (which are highly mobile in nature). In FIG. 14, there is provided a general depiction of this electrical phenomenon or behavior. In FIG. 14, there is shown a graph or plot of the threshold voltage (Vₜₕ) distributions with respect to the eight programmed states (i.e., State “A” through State “G”, including the “Erased” State) of a population of memory cells. Therefore, in this particular example, the memory cells are TLC-type memory cells. As indicated, for each programmed state, there appears a respective solid threshold voltage (Vₜₕ) distribution curve as intended, with each distribution curve having a certain voltage range or voltage width. For example, as shown in FIG. 14, the threshold voltage (Vₜₕ) distribution curve corresponding to “Program State ‘G’” has a voltage range or width that is indicated by an arrow “X.” However, further depicted in FIG. 14 is a discernible widening in the threshold voltage (Vₜₕ) distribution curve with respect to each program state, as indicated by the dotted curves. Accordingly, as pictured in FIG. 14, once programmed, the actual threshold voltage (Vₜₕ) distribution curve of “Program State ‘G’” (for example), has a voltage range or width indicated by an arrow “Y,” wherein the distribution width of arrow “Y” is, by comparison, greater than the intended distribution width of arrow “X.”

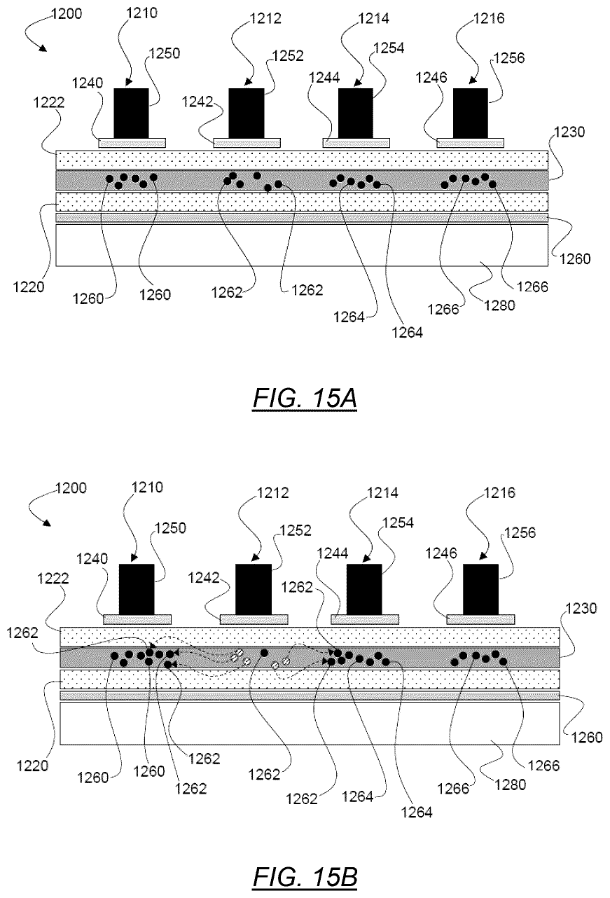

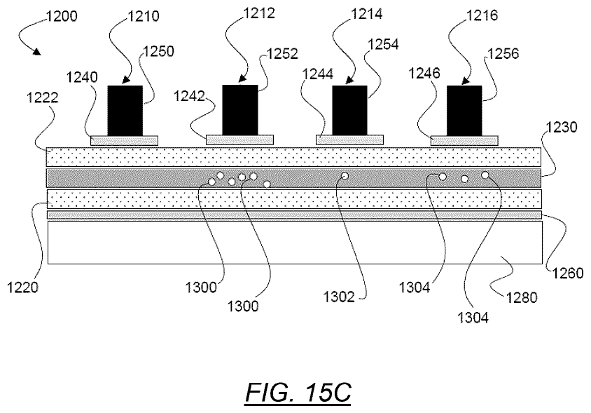

Additionally, as mentioned above, it is possible that once a memory structure has undergone a programming operation, the electron charges that are being retained at the floating gate or the charge trapping layer may shift or migrate in, for example, a lateral direction. Furthermore, this shift or migration may occur over time and/or quickly as a result of certain electrical phenomena or electrical behaviors (e.g., electrostatic behavior). Consequently, this displacement or this scattering of some of the electron charges once programmed can present various challenges to the overall performance of the memory structure, which include, for example, with respect to the reliability, efficiency, and power consumption of the memory structure. Referring now to FIGS. 15A-15C, there is provided a series of depictions that demonstrate a particular challenge resulting from the unintended shift or migration of electron charges subsequent to the programming of a memory structure.

Beginning at FIG. 15A, there is generally depicted, according to an exemplary embodiment, a representative section 1200 of a three-dimensional NAND-type memory block. According to this particular depiction, section 1200 comprises four memory cells 1210, 1212, 1214, and 1216. Each memory cell comprises a control gate, 1240, 1241, 1244, and 1246, respectively, at an intersection with a respective word line (WL) 1250, 1252, 1254, and 1256. Further, section 1200 may be comprised of one or more material layers that may include, for example, a charge trapping layer 1230 disposed between two insulating layers 1220, 1222, a channel 1260, and an underlying semiconductor substrate 1280. According to this particular embodiment, the two insulating layers 1220, 1222 may be comprise of, for example, an oxide material.

The specific programming order of the memory cells 1210, 1212, 1214, and 1216 may be pre-determined according to an assignment protocol that could be stored, for example, within the memory device itself. In this particular instance, the determined programming order, with respect to section 1200, commences at word line 1250 and, if continuing onward therefrom, proceeds to the right (i.e., to word line 1252, then word line 1254, . . . , etc.) during a given programming/erase cycle. In the depiction in FIG. 15A, a programming/erase cycle has been completed with respect to word lines 1250 through 1256 and, as a result, a number of electron charges are present at the charge trapping layer 1230, in accordance with a programmed state. Namely, a number of electron charges 1260 are present at the memory cell 1210. Similarly, a number of electron charges 1262 are present at the memory cell 1212. In addition, a number of electron charges 1264 are present at the memory cell 1214. Furthermore, a number of electron charges 1266 are present at the memory cell 1216.

Referring now to FIG. 15B, there is depicted a current state of representative section 1200 of FIG. 15A in which, over time or relatively quickly, some percentage of the electron charges present at the charge trapping layer 1230 (as a result of the programming operation described above with respect to FIG. 15A) have now shifted or migrated in a lateral direction. Specifically, in this particular illustrative example, certain ones of the electron charges 1262 initially present at memory cell 1212 have shifted or migrated to the neighboring memory cells 1210 and 1214. For example, as indicated by the dotted arrows that are pointing in a lefthand direction, three of the electron charges 1262 have traveled from memory cell 1212 in a lateral direction such that they are now present at neighboring memory cell 1210. Also, as is indicated by the dotted arrows that are pointing in a righthand direction, two of the electron charges 1262 have traveled from memory cell 1212 in a lateral direction such that they are now present at neighboring memory cell 1214. Therefore, as visually depicted in FIG. 15B, the number of electron charges in aggregate that are now present at memory cell 1210 and memory cell 1214 have increased and, correspondingly, the number of electron charges in aggregate that are now present at memory cell 1212 have decreased. As a result, the actual threshold voltage (Vₜₕ) distributions of each of the programmed memory cells 1210, 1212, and 1214 are now skewed relative to intended threshold voltage (Vₜₕ) distributions exhibited by the programmed memory cells 1210, 1212, and 1214 immediately following the programming operation depicted in FIG. 15A.

Referring now to FIG. 15C, there is depicted a current state of representative section 1200 as a result of an erase operation occurring after the programming operation shown in FIG. 15A, as well as after the programmed memory cells of the representative section 1200 have experienced a degree of lateral shift or migration of the deposited electron charges as shown in FIG. 15B. As discussed above, in order to perform an erase operation of a memory block, a relatively high erase biasing voltage (i.e., VERA) level that, according to certain exemplary embodiments, is within the approximate range of 20 volts to 25 volts, is applied to the channel region (e.g., the channel 1260 in FIGS. 15A and 15B) of the memory block. In addition, a relatively low voltage bias (i.e., VERA_WL) level is further applied to the word line(s) of the memory block. According to certain exemplary embodiments, the voltage (VERA_WL) level applied to the word line(s) may be within an approximate range of, for example, 0.5 volts to 2.0 volts. Thus, a significant electrical potential is created as a result of this considerable voltage difference between the erase biasing voltage (VERA) level that is applied to the channel region and the voltage (VERA_WL) level that is applied to the word line(s). This electrical potential causes the electron charges (e.g., the post-programming electron charges 1260, 1262, 1264, and 1266 in FIG. 15A) present at the charge trapping layer (e.g., the charge trapping layer 1230 in FIGS. 15A and 15B) to move or tunnel out of the charge trapping layer, thereby placing the memory cells into an “erased” state.

As described in greater detail above, an erase operation is applied uniformly to the memory block, and to the entirety of the memory block at each erase operation, irrespective of differing threshold voltage (Vₜₕ) distributions amongst the memory cells (or elements) of the memory block. However, in the circumstance in which there are memory cells (or elements) within a memory block that have an absence of programmed electron charges at the charge trapping layer, or have a significantly fewer number of electron charges present at the charge trapping layer in comparison to the electron charge populations of neighboring programmed memory cells, the application of a large electrical potential across the channel region during an erase operation may lead to deviations in the electrical characteristics or electrical properties of the memory cells. FIG. 15C depicts one example of an unintended change or disturbance in the electrical behavior of several memory cells as a result of an erase operation being uniformly applied to the entire memory block comprising representative section 1200. As depicted, the electron charges 1260, 1262, 1264, and 1266 that were previously present at the programmed memory cells 1210, 1212, 1214, and 1216, have now completely vanished from the charge trapping layer 1230 as an intended result of the erase operation. Additionally however, as is depicted in FIG. 15C, the applied electrical potential may unintentionally induce a number of positive charges 1300, 1302, and 1304 that now populate the charge trapping layer 1230 of memory cells 1212, 1214, and 1214, as a result of the imbalance of retained electron charges between memory cells due to the lateral shift or migration at the point in time depicted in FIG. 15B. Consequently, although each of the memory cells 1210, 1212, 1214, and 1216 should now be in an “erased” state after the erase operation, these induced positive charges 1300, 1302, and 1304 may skew or change the electrical parameters or the electrical characteristics (e.g., the threshold voltage (Vₜₕ) margin) of the memory cells, thus potentially resulting in a cascade of performance challenges.

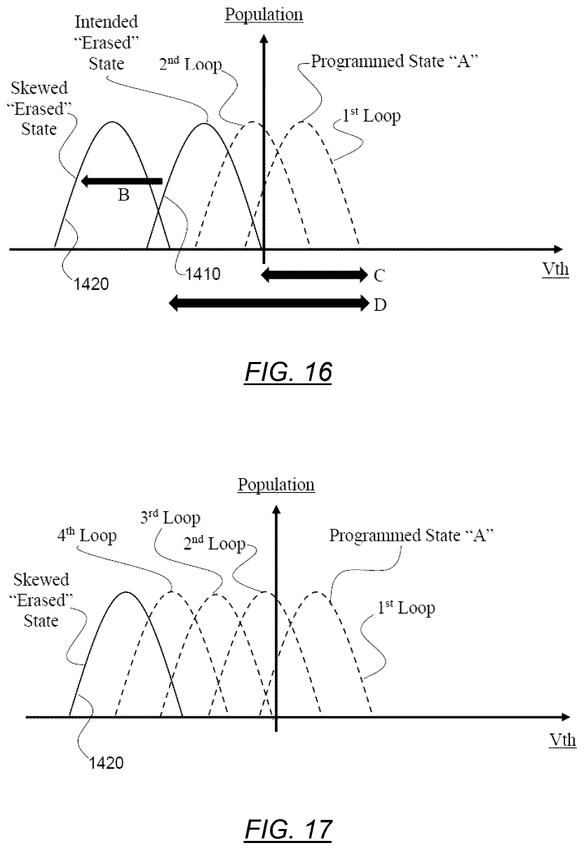

Examples of some performance challenges that may possibly occur are depicted in a general manner in FIGS. 16 and 17. The distribution graph or plot that is set forth in FIG. 16 indicates generally a threshold voltage (Vₜₕ) distribution of an example population that is comprised of memory cells of a representative memory block. As indicated, according to this particular example, memory cells that are programmed to a “Program State ‘A’” require two successive erase/verify loops to empty the charge trapping layer (e.g., 1230 in FIG. 15A) of electron charge(s) that are present at the “Program State ‘A’” in order to arrive at an intended “erased” state (which is depicted at curve 1410). However, with respect to any memory cells having any induced positive charges that are present at its charge trapping layer (e.g., see the memory cells 1212, 1214, and 1216 as they appear in FIG. 15C) as a result of the electrical potential created by the erase operation, a decrease in the threshold voltage (Vₜₕ) distribution margin of the memory cell may occur, thereby skewing the “erased” state of the memory cell. Accordingly, as indicated in FIG. 16, the “erased” state has experienced a leftward shift in the direction of arrow “B” as depicted at curve 1420. This wholesale lower shift in the threshold voltage (Vₜₕ) distribution of the “erased” state of a memory cell may, therefore, be characterized or referred to as a “deep erase” condition.

Problematic ramifications may arise as a result of having a “deep erase” condition. Various examples are illustrated in a general manner in the distribution graph or plot that is provided in FIG. 17. For example, as a result of a memory cell having a skewed downward “erased” state, any future or any prospective programming of that memory cell that may occur during a subsequent programming/erase cycle may itself be adversely affected. As depicted in FIG. 17, a “deep erase” condition of a memory cell may compound the requisite number of programming loops that are required to reach a programmed state. As illustrated in FIG. 17, a memory cell exhibiting an intended “erased” state has a narrower threshold voltage (Vₜₕ) distribution margin/range (see e.g., width “C” in FIG. 16) between its “erased” state and, for example, a “Program State ‘A’”, in comparison to the threshold voltage (Vₜₕ) distribution margin/range between a programmed state and a skewed “erased” state having a downward directional shift (see e.g., width “D” in FIG. 16). Accordingly, this widening of the threshold voltage (Vₜₕ) distribution margin/range relative to the “erased” state of a memory cell may necessitate an increase in the number of programming/verify loops that are needed to reach a programmable state. For example, as demonstrated in FIG. 17, a total of four (4) programming loops are now required in order to reach the “Program State ‘A’”, whereas, as indicated in FIG. 16, when the erased state has not experienced any unintended distribution shift, only two (2) programming loops should be needed in order to reach “Program State ‘A’”. However, this increase in the number of required programming/verify loops lengthens the amount of time consumed during the programming operation, thereby impairing the efficiency of the memory device. Further, the added programming loops may place a higher stress and strain on the semiconductor materials of the memory device, thereby accelerating the wear and tear and, ultimately, the reliability and longevity of the memory device. In addition, the memory device will likely consume more power (e.g., ICC) due to these compensatory loop increases in the programming operation of the device.

Accordingly, the following description details certain exemplary embodiments of mechanisms that operate to ameliorate or to reduce, during the programming stage of a programming/erase cycle, any unintended shift or widening in the threshold voltage (Vₜₕ) distribution of the programmed states of a memory structure.

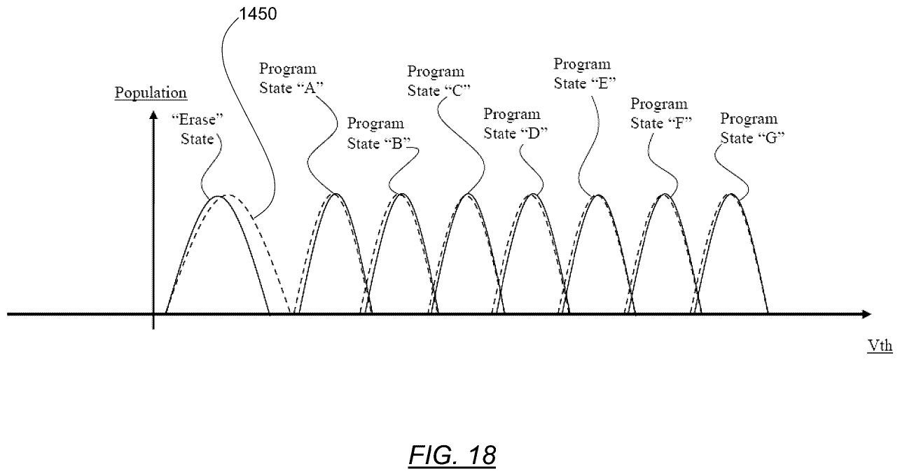

Beginning at FIG. 18, there is depicted a distribution graph or plot that indicates the respective threshold voltage (Vₜₕ) distribution curves for each of “Program State ‘A’” through “Program State ‘G’” as a result of a programming operation according to an exemplary embodiment thereof. Accordingly, in this particular example, for illustrative purposes, the programming operation is applied with respect to the eight programmable states of a TLC-type memory structure. However, in contrast to the programming operation demonstrated in the distribution plot in FIG. 14, the programming operation that is evidenced in FIG. 18 further comprises the programming of the “Erase State” as the first programmed state. As illustrated in FIG. 18, the programming of the “Erase State” operates to tighten the voltage range or width of the threshold voltage (Vₜₕ) distribution with respect to each of the programmed states, thereby lessening the ability of electron charges that are retained at the floating gate or charge trapping layer of memory cells to shift or migrate their position over time. As indicated by the dotted distribution curves that are shown in FIG. 18, the degree of disturbance in the threshold voltage (Vₜₕ) distributions is comparatively less than is experienced subsequent to the programming operation resulting in the distribution plot in FIG. 14.

Thus, in circumstances in which the reliability of the programmed data is the most significant, or takes a higher priority, with respect to the various performance parameters of a memory device, this programming approach or methodology (or algorithm) of programming an “Erase State” as an initial program state in the programming order may be advantageously implemented. For example, such a programming approach may be specifically applied with respect to only certain types of data or certain types of memory, or only for particular data applications or uses. Furthermore, such a programming approach may be selectively applied according to an executable command mode (or modes).

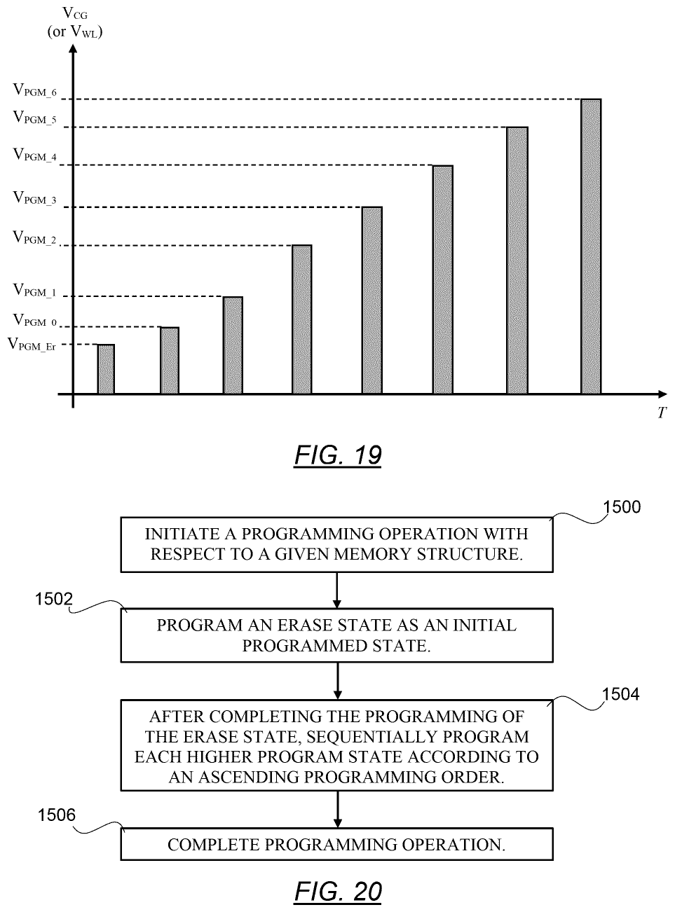

Referring now to FIG. 19, there is generally depicted a bar graph that indicates, as a function of time (7) (i.e., along the x-axis), an exemplary embodiment of a sequence of the programming voltage bias (V_{PGM}) levels that are applied to a given memory structure in accordance with the programming approach described just above with respect to the resulting threshold voltage (Vₜₕ) distribution plot that is set forth in FIG. 18. As indicated in FIG. 19, according to this particular programming sequence, a low programming voltage bias level, “V_{PGM_Er},” is first applied to the memory structure in order to program an “Erase State.” Thereafter, a relatively higher programming voltage bias level, “VPGM 0,” (wherein V_{PGM_0}>V_{PGM_Er}) is then applied to the memory structure in order to program the next highest program state, which is referenced in FIG. 18 as “Program State ‘A’”. Continuing onward, each of the remaining program states, e.g., “Program State ‘B’” through “Program State ‘G’”, are then sequentially programmed in an ascending order according to a correspondingly incremental increase in the programming voltage bias level (i.e., from “VPGM 1” through “VPGM 6”, wherein V_{PGM_1}<V_{PGM_2}<V_{PGM_3}<V_{PGM_4}<V_{PGM_5}<V_{PGM_6}) applied to the memory structure. To recap, FIG. 20 indicates a flow diagram that provides a general outline of the steps of the programming approach or methodology according to the exemplary embodiment depicted in FIGS. 18 and 19.

Beginning at step 1500, a program command is first received with respect to a given memory structure and, accordingly, a programming operation is initiated or commences. Therefore, at step 1502, a suitable programming voltage bias level is applied to the memory structure in order to program an “Erase State” as an initial programmed state. Next, after completing the programming of the “Erase State,” each higher program state is programmed according to an ascending programming order (see step 1504) by applying the suitable pre-determined programming voltage bias level(s) to the memory structure. Lastly, at step 1506, the programming operation is considered complete once each of the intended program states is programmed.

Importantly however, according to certain observations and data (experimental and in situ), the beneficial effect of tightening (or otherwise confining) the threshold voltage (Vₜₕ) distributions of the programmed states of a memory structure by first programming an “Erase State” during a programming operation is somewhat diluted or weakened by this particular programming sequence or order. Referring back to the distribution plot depicted in FIG. 18, as indicated by the actual threshold voltage (Vₜₕ) distribution curve (see dotted curve 1450) of the programmed “Erase State,” it may be possible that the subsequent application of the higher programming voltage bias (VPGM) levels after programming the “Erase State” and during the programming of the remaining program states will disturb (due to, for example, electrostatic coupling) the upper tail of the threshold voltage (Vₜₕ) distribution curve of the “Erase State,” thereby skewing the threshold voltage (Vₜₕ) distribution of the “Erase State” in an upward direction. As a result, similar performance challenges to those intended to be addressed by this programming approach may actually still be experienced and revisited when under certain conditions.

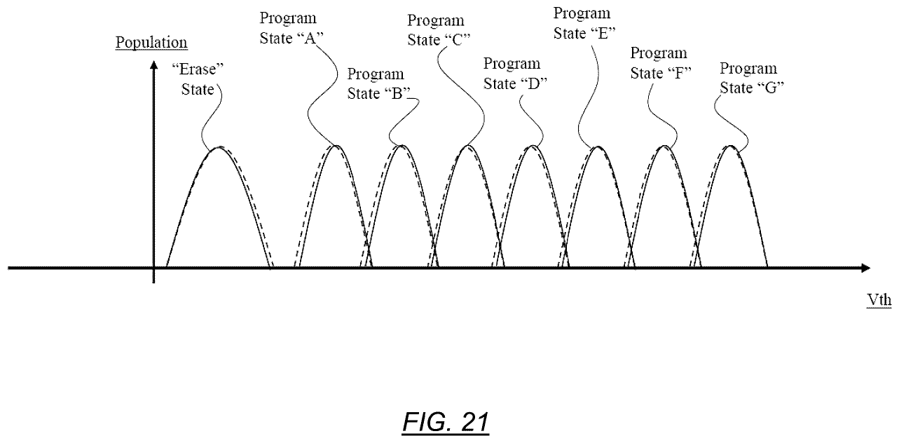

As such, FIGS. 21 through 23 depict a programming operation in accordance with a different exemplary embodiment that operates to tighten each of the threshold voltage (Vₜₕ) distributions of the programmed states, including the “Erase State.” Specifically, rather than programming an “Erase State” as the first program state in a programming sequence or programming order, the “Erase State” is instead programmed after finishing programming the highest program state and as the last (or final) program state of the programming sequence or programming order. In this way, because no further programming ensues following the “Erase State”, the resulting threshold voltage (Vₜₕ) distribution of the “Erase State” can no longer be disturbed as a result of a subsequent application of a higher programming voltage bias level. Accordingly, as depicted by the dotted curves in the distribution plot set forth in FIG. 21, a programming approach according to this methodology results not only in a tightening of the threshold voltage (Vₜₕ) distribution of, in this specific example, each of “Program State ‘A’” through “Program State ‘G’”, but also significantly and appreciably tightens the corresponding threshold voltage (Vₜₕ) distribution of the “Erase State” (as compared to the behavior that is exhibited in FIG. 18).

Importantly, it should also be noted that by programming the “Erase State” as the last programmed state within a programming order, the exact programming voltage bias level (V_{PGM_Er}) that is suitable for programming the “Erase State” may be precisely determined beforehand by utilizing the program verify information that is acquired (and stored) during the preceding programming of the other program states. This precise determination allows for programming the “Erase State” accurately and with the least number of programming loops possible, thereby improving the speed (T_{prog}) and the overall efficiency of the programming operation.

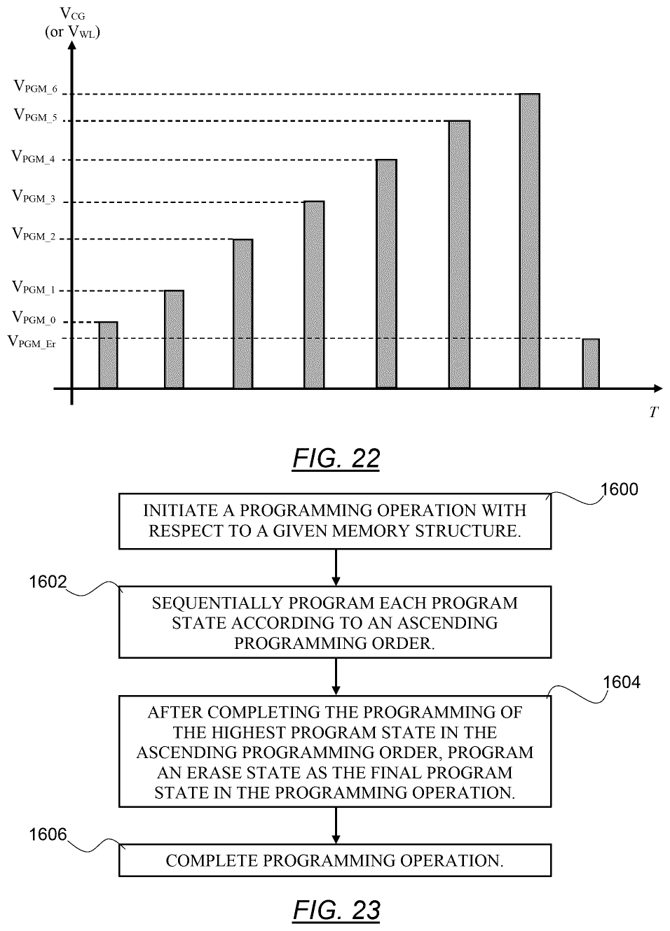

With respect to FIG. 22, generally depicted is a bar graph that, similar to the graph provided in FIG. 19, indicates a sequence of the applied respective programming voltage bias (VPGM) levels during a programming operation of a given memory structure. According to this particular embodiment, the programming operation is much the same as that that is depicted in FIG. 19 with the exception that the “Erase State” is programmed as the last program state, i.e., after the programming of all other program states is complete. Therefore, in the illustrative example demonstrated in FIG. 22, after applying the highest programming voltage bias level (V_{PGM_6}) as required to program the highest program state in the programming order, the programming voltage bias (VPGM) level no longer ascends upward. Rather, it is decreased, or ramped down, to a relatively low programming voltage bias level (V_{PGM_Er}) pre-determined as suitable for programming the “Erase State.”

Referring now to FIG. 23, depicted therein is a flow diagram that generally outlines several steps of an exemplary embodiment of a programming operation in which the last programmed state in the programming sequence or order is an “Erase State”. Beginning at step 1600, a programming operation is first initiated with respect to a given memory structure in response to receiving a program command (or series of commands) from, for example, a host controller or an on-chip controller. Accordingly, next at step 1602, each program state is sequentially programmed according to, for example, an ascending programming order in which each successive program state is at a higher threshold voltage (Vₜₕ) level than the program state programmed just prior thereto. (See, for example, the ascending programming order that is depicted in FIG. 22.) After completing the programming of the highest program state in the ascending programming order, an “Erase State” is then programmed as the final program state within the programming order (see step 1604). Once programming of the “Erase State” is complete, the programming operation is finished (see step 1606).

Importantly, it should be noted that due to the fact that the programming voltage bias (V_{PGM_Er}) level applied to the memory structure in order to program the “Erase State” is comparatively much lower than the programming voltage bias (VPGM) levels applied in programming each of the other program states, the programming of the “Erase State” at the conclusion or tail end of the programming sequence or order does not result in any discernible disturbance to the threshold voltage (Vₜₕ) distributions of the other programmed states. Furthermore, it should be noted that, also due to the “Erase State” being, in essence, the lowest program state of all the programmed states, an inhibit condition can be (and is) imposed with respect to the other (higher) program states while programming the “Erase State” as the final program state. Thus, any data that is stored in cache (e.g., program verify data) during the programming operation in, for example, one or more data latches, can be released as needed without any delay. Rather, during the programming of the “Erase State,” all program states are treated as the “Erase State” and, as such, there is no need to recall or elicit from the data cache which memory elements (e.g., cells) of the memory structure are to be placed under the “Erase State.”

The above discussion is meant to be illustrative of the principles and various embodiments of the present invention. Numerous variations and modifications will become apparent to those skilled in the art once the above disclosure is fully appreciated, and may be employed without departing from the scope of the disclosure, limited only by any practical limitations related to the materials and physical principles of the devices that are described. It is intended that the following claims be interpreted to embrace all such variations and modifications.

What is claimed is:

1. A method for performing a programming memory operation with respect to a memory structure, the method comprising:
initiating a programming operation with respect to multiple program states of a non-volatile memory structure;
programming each of the multiple program states according to a programming order; and
after completing the programming of each of the multiple program states, programming an erase state as the final program state of the programming order.

2. The method according to claim 1, wherein the memory structure is a three-dimensional memory structure comprising a plurality of NAND-type memory cells.

3. The method according to claim 1, wherein:
the programming order comprises an ascending programming order in which each program state that is being programmed is a higher program state than the program state just previously programmed.

4. The method according to claim 3, wherein the erase state is programmed after the completion of the programming of a highest program state of the multiple program states.

5. The method according to claim 4, wherein the erase state is a lower program state than any program state of the multiple program states.

6. The method according to claim 4, wherein:
programming the erase state further comprises ramping down a programming voltage bias level applied to the memory structure following the completion of the programming of the highest program state of the multiple program states.

7. A memory controller, comprising:
a communication pathway configured to couple to a non-volatile memory structure; and
the memory controller is configured to:
initiate a programming operation with respect to multiple program states of the memory structure;
program each of the multiple program states according to a programming order; and
after completing the programming of each of the multiple program states, program an erase state as the final program state of the programming order.

8. The memory controller according to claim 7, wherein the memory structure is a three-dimensional memory structure comprising a plurality of NAND-type memory cells.

9. The memory controller according to claim 7, wherein:
the programming order comprises an ascending programming order in which each program state that is being programmed is a higher program state than the program state just previously programmed.

10. The memory controller according to claim 9, wherein the erase state is programmed after the completion of the programming of a highest program state of the multiple program states.

11. The memory controller according to claim 10, wherein the erase state is a lower program state than any program state of the multiple program states.

12. The memory controller according to claim 10, wherein programming of the erase state further comprises the memory controller configured to ramp down a programming voltage bias level applied to the memory structure following completion of the programming of the highest program state of the multiple program states.

13. A non-volatile memory system, comprising:
a memory structure; and
a memory controller coupled to the memory structure and:
initiating a programming operation with respect to multiple program states of a non-volatile memory structure;
programming each of the multiple program states according to a programming order; and
after completing the programming of each of the multiple program states, programming an erase state as the final program state of the programming order.

14. The memory system according to claim 13, wherein the memory structure is a three-dimensional memory structure comprising a plurality of NAND-type memory cells.

15. The memory system according to claim 13, wherein:
the programming order comprises an ascending programming order in which each program state that is being programmed is a higher program state than the program state just previously programmed.

16. The memory system according to claim 15, wherein the erase state is programmed after the completion of the programming of a highest program state of the multiple program states.

17. The memory system according to claim 16, wherein the erase state is a lower program state than any program state of the multiple program states.

18. The memory system according to claim 16, wherein:
programming the erase state further comprises ramping down a programming voltage bias level applied to the memory structure following the completion of the programming of the highest program state of the multiple program states.
